(19) United States
(12) Patent Application Publication
(10) Pub. No.: US 2020/0379282 A1
(43) Pub. Date: Dec. 3, 2020

(54) PHOTO-ALIGNING EXPOSURE DEVICE

(71) Applicants: V TECHNOLOGY CO., LTD., Kanagawa (JP); SHARP KABUSHIKI KAISHA, Osaka (JP)

(72) Inventors: Yuji Yoshida, Kanagawa (JP); Satoshi Ikeda, Kanagawa (JP); Toshinari Arai, Kanagawa (JP); Isamu Miyake, Osaka (JP); Takashi Katayama, Osaka (JP); Akira Hirai, Osaka (JP)

(73) Assignees: V TECHNOLOGY CO., LTD., Kanagawa (JP); SHARP KABUSHIKI KAISHA, Osaka (JP)

(21) Appl. No.: 16/636,784

(22) PCT Filed: Aug. 6, 2018
(86) PCT No.: PCT/JP2018/029427

§ 371 Date: Feb. 5, 2020

(30) Foreign Application Priority Data
Aug. 9, 2017 (JP) 2017-154409

(51) Int. Cl. G02F 1/13; G02F 1/1337; G03F 7/20

(52) U.S. Cl. CPC G02F 1/1303; G03F 7/70191; G02F 1/133788

(57) ABSTRACT

A photo-aligning exposure device that performs a photo-aligning process by performing scanning exposure on an irradiated plane in one direction includes: a light source that emits scattering light toward the irradiated plane; an optical filter that selectively emits an ultraviolet ray out of the light emitted from the light source; and an irradiation angle restriction member that selectively emits light with which irradiation is diagonally performed with respect to the scanning direction out of the light emitted from the optical filter. The irradiation angle restriction member has a plurality of flat-plate-shaped light direction restriction plates slanted at a certain angle with respect to the irradiated plane and arrayed in parallel along the scanning direction at a predetermined distance.

### TECHNICAL FIELD

The present invention relates to an exposure device used for performing photo alignment of liquid crystal.

### BACKGROUND ART

The stabilization of a pre-tilt angle in a liquid crystal alignment process that is essential in the production of liquid crystal displays (LCDs) is an important object to provide LCDs with higher definition. The pre-tilt angle is an angle formed by the major axis of liquid crystal molecules along a liquid crystal alignment axis and an alignment plane, and greatly affects the display characteristics of the LCD. Therefore, it is essential to stably develop the pre-tilt angle in order to attain an LCD with a high display quality.

The photo-aligning process has become popular as a processing method replacing a rubbing process because a more uniform alignment process can be performed, as well as because it is a noncontact process that solves contamination caused by dust on the alignment film and electrostatic damage on a TFT substrate. Diagonal exposure is known as an exposure method for developing the pre-tilt angle by the photo-aligning process.

The diagonal exposure is to irradiate a film to be irradiated serving as the alignment film with a polarized ultraviolet ray at a predetermined angle from a normal direction of the film Hitherto, an exposure device for performing the diagonal exposure is provided with an irradiation unit that sets an irradiation angle with respect to the film to be irradiated via a plurality of reflecting plates with use of a light source with high directivity (see PTL 1).

### CITATION LIST

### Patent Literature

[PTL 1] Japanese Patent Application Laid-open No. 2011-175025

### SUMMARY OF INVENTION

### Technical Problem

The abovementioned conventional exposure device that performs the diagonal exposure has a problem in that the light source that can be used therein is limited to a relatively expensive light source with high directivity, and a problem in that the irradiation unit is up sized because the optical path lengths are set to be long in order to prevent the illuminance distribution on the irradiated plane obtained when the irradiated plane is diagonally irradiated from becoming ununiform due to the difference in the optical path lengths, and because space for securing the plurality of reflecting plates and the optical path lengths is needed.

An object of the present invention is to solve the problems as above. In other words, an object of the present invention is to enable an inexpensive scattering light source (volumetric light source) to be used, to obtain a uniform illuminance distribution in a compact form, and the like, in a photo-aligning exposure device that performs diagonal exposure in order to develop a pre-tilt angle.

### Solution to Problem

In order to solve the problems as above, the present invention has the following configuration.

There is provided a photo-aligning exposure device that performs a photo-aligning process by performing scanning exposure on an irradiated plane in one direction, the photo-aligning exposure device including: a light source that emits scattering light toward the irradiated plane; an optical filter that selectively emits an ultraviolet ray out of the light emitted from the light source; and an irradiation angle restriction member that selectively emits light with which irradiation is diagonally performed with respect to a scanning direction out of the light emitted from the optical filter. In the photo-aligning exposure device, the irradiation angle restriction member has a plurality of flat-plate-shaped light direction restriction plates slanted at a certain angle with respect to the irradiated plane and arrayed in parallel along the scanning direction at a predetermined distance.

### BRIEF DESCRIPTION OF DRAWINGS

FIG. 1 (a) is an explanatory view illustrating a photo-aligning exposure device according to an embodiment of the present invention (explanatory view seen from the side).

FIG. 1 (b) is an explanatory view illustrating a photo-aligning exposure device according to an embodiment of the present invention (explanatory view seen from the front).

FIG. 2 is an explanatory view illustrating a configuration example of an irradiation angle restriction member.

FIG. 3 is an explanatory view illustrating a photo-aligning exposure device according to another embodiment of the present invention.

### DESCRIPTION OF EMBODIMENTS

Embodiments of the present invention are described below with reference to the accompanying drawings. In the description below, the same reference symbols in different drawings indicate sections with the same functions, and overlapping descriptions in the drawings are omitted, as appropriate.

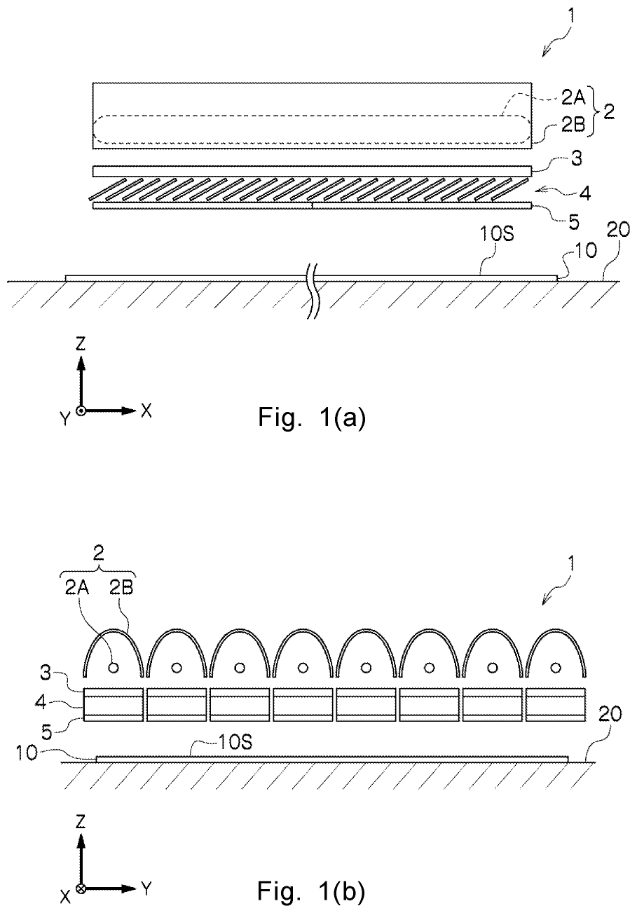

In FIGS. 1 (a) and 1 (b), a photo-aligning exposure device 1 includes a light source 2, an optical filter 3, an irradiation angle restriction member 4, and a polarizer 5, and performs a photo-aligning process by performing scanning exposure on an irradiated plane 10S on a substrate 10 supported on a stage 20 in one direction (the X direction in FIGS. 1 (a) and 1 (b)). The scanning exposure at this time may be performed by fixing the photo-aligning exposure device 1 and moving the substrate 10 to the X direction in FIGS. 1 (a) and 1 (b), or may be performed by fixing the substrate 10 and moving the photo-aligning exposure device 1 to the opposite direction (the −X direction) of the X direction in FIGS. 1 (a) and 1 (b). The scanning exposure may be performed while moving both of the substrate 10 and the photo-aligning exposure device 1.

The light source 2 emits scattering light toward the irradiated plane 10S, and includes a vertically long lamp 2A of which longitudinal direction is the scanning direction (the X direction in FIGS. 1 (a) and 1 (b)), and a reflecting mirror 2B that is vertically long along the lamp 2A and directs the light emitted from the lamp 2A toward the irradiated plane 10S. The reflecting mirror 2B has a reflecting plane of which cross section (Y-Z cross section) that intersects with the scanning direction is a concave curve shape.

The optical filter 3 selectively emits an ultraviolet ray out of the light emitted from the light source 2 (serves as band-pass the filter). The polarizer 5 is a polarizing plate, a wire grid polarizer, or the like, and is arranged between the irradiation angle restriction member 4 and the irradiated plane 10S. The angle of the polarizer 5 is adjusted so that the polarized axis is directed toward the direction set with respect to the scanning direction (the X direction in FIGS. 1 (a) and 1 (b)).

The irradiation angle restriction member 4 selectively emits the light with which irradiation is diagonally performed with respect to the scanning direction (the X direction in FIGS. 1 (a) and 1 (b)) out of the light (ultraviolet ray) emitted from the optical filter 3. Therefore, the irradiation angle restriction member 4 includes a plurality of flat-plate-shaped light direction restriction plates 40.

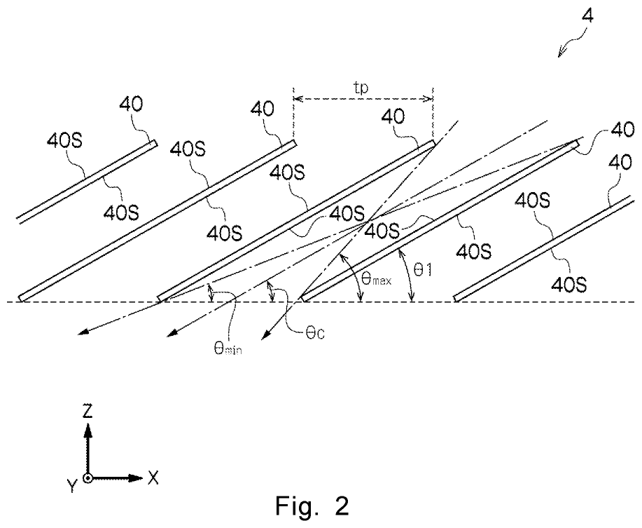

As illustrated in FIG. 2, the light direction restriction plates 40 are flat-plate-shaped members and are slanted at a certain angle θ1 with respect to the irradiated plane 10S. The plurality of light direction restriction plates 40 are arrayed in parallel along the scanning direction (the X direction in FIG. 2) at a predetermined distance tp. It is preferred that ultraviolet ray absorbing planes 40S be formed on both sides of the light direction restriction plate 40.

According to the photo-aligning exposure device 1 as above, the scattering light emitted from the lamp 2A and reflected by the reflecting mirror 2B is emitted from the light source 2, and passes through the optical filter 3, to thereby become an ultraviolet ray with a predetermined wavelength. By passing through the irradiation angle restriction member 4, the ultraviolet ray becomes an ultraviolet ray with which the irradiated plane 10S is diagonally irradiated in a predetermined direction. Then, the ultraviolet ray passes through the polarizer 5, to thereby become a polarized ultraviolet ray with which the irradiated plane 10S is irradiated.

Now, as illustrated in FIG. 2, in the irradiation angle restriction member 4, the light (ultraviolet ray) that has hit the ultraviolet ray absorbing planes 40S when passing through the light direction restriction plates 40 arranged in parallel at the distance tp is absorbed and is prevented from passing therethrough, and hence the irradiation angle is limited to an angle between a maximum irradiation beam angle θₘₐₓ and a minimum irradiation beam angle θₘᵢₙ. The irradiation angle is a predetermined range around a center irradiation beam angle θc in the same direction as a slant angle θ1 with respect to the scanning direction (the X direction in FIG. 2) of the light direction restriction plates 40, but the variation in the angle range can be suppressed by narrowing the distance tp.

The irradiation angle of the light that has passed through the irradiation angle restriction member 4 as above for the irradiated plane 10S is limited. However, when the light passing through the optical filter 3 is focused on, only the diagonally passing light out of the light passing through the optical filter 3 is selected and the irradiation is performed with the light. The optical filter 3 generally has an angular dependence, and hence the wavelength of the light diagonally passing through the optical filter 3 shifts to a low wavelength side with respect to the wavelength (set wavelength) of the light vertically passing through the optical filter 3. Therefore, in order to set the exposure wavelength to a desired wavelength (for example, 313 nm), a selective wavelength setting value of the optical filter 3 needs to be set to a value shifted (for example, 313 nm+36 nm=349 nm) to the long wavelength side with respect to the target exposure wavelength.

When the photo-aligning exposure device 1 as above is used, the diagonal exposure that can develop the pre-tilt angle by the photo-aligning process with use of a relatively inexpensive scattering light source can be performed. At this time, the length of the irradiation range of the light with which irradiation is simultaneously performed along the scanning direction by the photo-aligning exposure device 1 is about the same as the length of the light source 2 in the longitudinal direction thereof, and a uniform illuminance distribution can be obtained regardless of the distance between the photo-aligning exposure device 1 and the irradiated plane 10S within the range. As a result, the exposure can be performed in a compact form in which the photo-aligning exposure device 1 is brought close to the irradiated plane 10S.

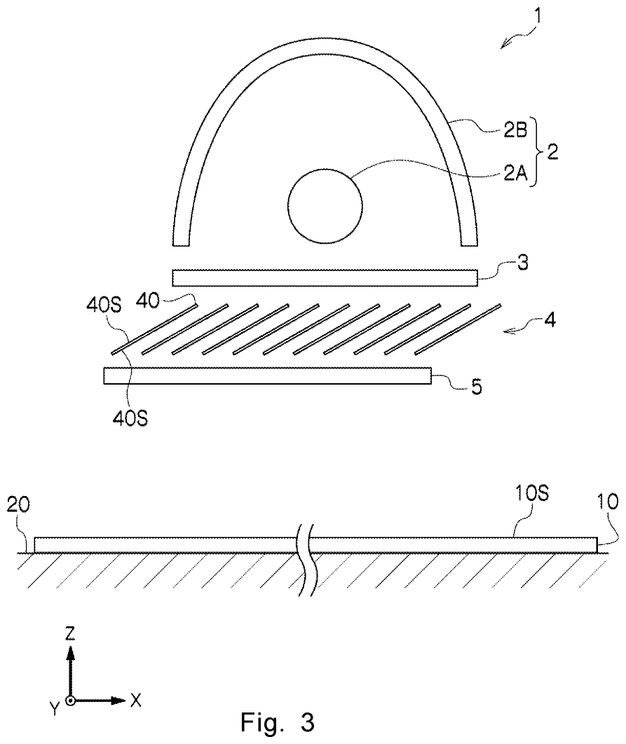

FIG. 3 illustrates the photo-aligning exposure device 1 according to another embodiment. In this example, the light source 2 is arranged in a horizontally long form in which the direction (the Y direction in FIG. 3) that intersects with the scanning direction (the X direction in FIG. 3) is the longitudinal direction. Even when the light source 2 as above is used, the photo-aligning exposure device 1 that performs the photo-aligning process by the diagonal exposure with use of a scattering light source can be acquired by arranging the optical filter 3, the irradiation angle restriction member 4 in which the plurality of light direction restriction plates 40 are arranged in parallel, and the polarizer 5 as in the example described above.

### Example 1

An alignment agent “RN 4000” (manufactured by Nissan Chemical Industries, Ltd.) was applied on two glass substrates by spin coating, and was dried at 80° C. for 1 minute. The alignment film thickness at this time was 100 nm. Then, exposure was performed by the photo-aligning exposure device 1. A 313-nm band-pass filter was used as the optical filter 3. A wire grid polarizing plate was used as the polarizer 5, and the degree of polarization was about 100 at 313 nm. The 313-nm exposure amount was 5 mJ/cm² when the light receiving plane was arranged in parallel with the exposure stage and measurement was performed with UIT250-S313 (manufactured by USHIO INC.). Then, main firing was performed with a hot plate (EC-1200N manufactured by AS ONE Corporation.) at 140° C. for 20 minutes, and the formation of the film was finished. Out of the glass substrates on which the film was formed, Structbond HC-913FP (manufactured by Mitsui Chemicals, Inc.) that is a sealant was drawn on one glass substrate and Micropearl SP-2035 (manufactured by SEKISUI CHEMICAL CO., LTD.) that are plastic beads spacers were sprayed on the other glass substrate. A vacuum injection cell was manufactured by bonding the two glass substrates to each other and firing the glass substrates at 120° C. for 60 minutes. A liquid crystal cell was completed by encapsulating MLC 2003 (manufactured by Merck KGaA) into the cell, and performing a realignment process at 130° C. for 10 minutes after a sealing process.

The pre-tilt angle of the liquid crystal cell was measured by crystal rotation. Axoscan (manufactured by Axometrics, Inc.) was used for the measurement. As a result, the pre-tilt angle was 25 degrees. When the cell was sandwiched between two crossed Nicols polarizers and was observed, the cell was a uniformly-aligned liquid crystal cell.

### Example 21

A liquid crystal cell was completed by performing a process in a manner similar to that in Example 1 except for the exposure amount being 10 mJ/cm². The pre-tilt angle of the liquid crystal cell was 6 degrees. When the cell was sandwiched between two crossed Nicols polarizers and was observed, the cell was a uniformly-aligned liquid crystal cell.

### Example 31

The liquid crystal cell was completed by performing a process in a manner similar to that in Example 2 except for (the photo-aligning exposure device 1 that does not use a louver but uses a shielding plate being used). The pre-tilt angle of the liquid crystal cell was 65 degrees. When the cell was sandwiched between two crossed Nicols polarizers and was observed, the cell was a uniformly-aligned liquid crystal cell.

As described above, according to the photo-aligning exposure device 1 according to the embodiment of the present invention, an inexpensive scattering light source (volumetric light source) can be used and a uniform illuminance distribution can be obtained in a compact form in the exposure device that performs diagonal exposure in order to develop a pre-tilt angle.

The embodiments of the present invention have been described above in detail with reference to the accompanying drawings. However, specific configurations are not limited to those embodiments, and design changes and the like are encompassed by the present invention without departing from the spirit of the present invention. The embodiments described above can be combined by applying features thereof to each other unless contradictions and problems arise in the object, configuration, and the like.

### REFERENCE SIGNS LIST

1 Photo-aligning exposure device
2 Light source
2A Lamp
2B Reflecting mirror
3 Optical filter
4 Irradiation angle restriction member
40 Light direction restriction plate
40S Ultraviolet ray absorbing plane
5 Polarizer
10 Substrate
10S Irradiated plane
20 Stage

1. A photo-aligning exposure device that performs a photo-aligning process by performing scanning exposure on an irradiated plane in one direction, the photo-aligning exposure device comprising:
a light source that emits scattering light toward the irradiated plane;
an optical filter that selectively emits an ultraviolet ray out of the light emitted from the light source; and
an irradiation angle restriction member that selectively emits light with which irradiation is diagonally performed with respect to the scanning direction out of the light emitted from the optical filter, wherein
the irradiation angle restriction member has a plurality of flat-plate-shaped light direction restriction plates slanted at a certain angle with respect to the irradiated plane and arrayed in parallel along the scanning direction at a predetermined distance.

2. The photo-aligning exposure device according to claim 1, wherein the flat-plate-shaped light direction restriction plates have ultraviolet ray absorbing planes formed on both sides of the flat-plate-shaped light direction restriction plate.

3. The photo-aligning exposure device according to claim 1, wherein the light source is arranged in a vertically long form in which the scanning direction is set as a longitudinal direction.

4. The photo-aligning exposure device according to claim 1, wherein the light source is arranged in a horizontally long form in which a direction that intersects with the scanning direction is set as a longitudinal direction.

5. The photo-aligning exposure device according to claim 1, wherein a polarizer is arranged between the irradiation angle restriction member and the irradiated plane.

6. The photo-aligning exposure device according to claim 1, wherein the optical filter is arranged in parallel with the irradiated plane, and a selective wavelength setting value of the optical filter is a value shifted to a long wavelength side with respect to a target exposure wavelength.
